(19) United States
(12) Patent Application Publication
(10) Pub. No.: US 2020/0149185 A1
(43) Pub. Date: May 14, 2020

(54) REFLECTIVE SCREEN OF A MONOCRYSTAL GROWTH FURNACE AND THE MONOCRYSTAL GROWTH FURNACE

(71) Applicant: ZING SEMICONDUCTOR CORPORATION, Shanghai (CN)

(72) Inventors: WEIMIN SHEN, Shanghai (CN); JIN FAN, Shanghai (CN); GANG WANG, Shanghai (CN); WEE TECK TAN, Shanghai (CN)

(21) Appl. No.: 16/676,399

(22) Filed: Nov. 6, 2019

(30) Foreign Application Priority Data
Nov. 12, 2018 (CN) 201811340095.6

(51) Int. Cl. C30B 15/14; C30B 29/06

(52) U.S. Cl. CPC C30B 15/14; C30B 29/06

(57) ABSTRACT

The present application provides a reflective screen of a monocrystal growth furnace and the monocrystal growth furnace. The reflective screen comprises an inner cylinder, an outer cylinder, a thermal insulating material sandwiched between the inner and the outer cylinders, and a thermal insulating pad disposed at the joint of the inner and the outer cylinders. The reflective screen and the monocrystal growth furnace are able to decrease the thermal transmittance from the outer cylinder to the inner cylinder, increase the vertical temperature gradient of the ingot, and prevent or decrease the silicon oxides evaporated from the molten silicon to condensate on the outer cylinder of the reflective screen. Thereby, polycrystalline caused by the oxides falling into the molten silicon can be reduced. Moreover, the thermal power required during the growth of monocrystalline silicon can be reduced because of the reduction of unnecessary thermal transmittance.

### BACKGROUND OF THE INVENTION

### 1. Field of the Invention

The present application relates to the technical field of the semiconductor, in particular to a reflective screen of a monocrystal growth furnace and the monocrystal growth furnace.

### 2. Description of the Related Art

Along with the developments of techniques and new electronic products, the requirements of monocrystalline silicon with large diameter increases rapidly. Methods for growing monocrystalline silicon include Czochralski process (CZ), floating zone process (FZ) and epitaxial growth. Czochralski process and floating zone process are used to grow the monocrystalline silicon ingot while epitaxial growth is used to grow the monocrystalline silicon film. Generally, CZ process is the most well-known process, and the prepared monocrystalline silicon is applied to integrated circuit, diode, epitaxial substrate, solar cell and the like.

CZ process comprises immersing a seed crystal into the molten silicon in the crucible of the monocrystal growth furnace, rotating the seed crystal and the crucible, and pulling the seed crystal to conduct the growing of neck, crown, shoulder, body and tail in order, and obtaining the monocrystalline silicon ingot. In the furnace, the reflective screen is able to prevent the heat radiation from the molten silicon and the crucible to the silicon crystal, increase the vertical temperature gradient of the ingot, control the crystal growth rate and the internal defects such as the crystal originated particle (COP) and the like. Further, the reflective screen is able to regulate the flow of inert gas fed from the upper part of the furnace to pass the surface of the molten silicon with a faster flow rate, thereby the contents of oxygen and impurities within the crystal can be controlled. However, the known reflective screen cannot effectively prevent the thermal transmittance from the outer cylinder to the inner cylinder.

Therefore, there is a need for a reflective screen of a monocrystal growth furnace and the monocrystal growth furnace that can solve the above problems.

### SUMMARY

A series of concepts in a simplified form is introduced here, which will be described in further detail in the detailed description. This summary of the present invention does not intend to limit the key elements or the essential technical features of the claimed technical solutions, nor intend to limit the scope of the claimed technical solution.

The present application provides a reflective screen of a monocrystal growth furnace, in which the reflective screen comprises an inner cylinder, an outer cylinder, a thermal insulating material sandwiched between the inner and the outer cylinders, and a thermal insulating pad disposed at the joint of the inner and the outer cylinders.

In one embodiment, the material of the thermal insulating pad comprises a quartz.

In one embodiment, the quartz is subjected to a coating treatment.

In one embodiment, the reflective screen comprises at least one thermal insulating pad.

In one embodiment, the thermal insulating pad comprises a first thermal insulating pad disposed on the bottom of the inner cylinder and/or a second thermal insulating pad disposed on the top of the inner cylinder.

In one embodiment, the thermal insulating pad comprises a second thermal insulating pad disposed on the top of the inner cylinder, and the reflective screen comprises an inverted cone-shaped body and an extension part extended from the upper end of the body, and the second thermal insulating pad further comprises a part disposed on the extension part and sandwiched between the inner and the outer cylinders.

In one embodiment, the material of the inner cylinder and/or the outer cylinder comprises a carbon/carbon composite (C/C) and/or a graphene.

The present application further provides a monocrystal growth furnace comprising: a furnace body, a crucible disposed in the furnace body, and a reflective screen of any of the above described embodiments, the reflective screen is above the crucible.

### BRIEF DESCRIPTION OF THE DRAWINGS

FIG. 1 illustrates, according to one embodiment of the present application, the structure of the reflective screen of the monocrystal growth furnace.

FIG. 2 illustrates, according to one embodiment of the present application, the structure of the monocrystal growth furnace.

FIG. 3a illustrates the analog temperature gradient of the reflective screen in prior art.

FIG. 3b illustrates the analog temperature gradient of the reflective screen according to one embodiment of the present application.

### DETAILED DESCRIPTION OF THE EMBODIMENTS

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

It should be understood that the present invention may be practiced in different forms and that neither should be construed to limit the scope of the disclosed examples. On the contrary, the examples are provided to achieve a full and complete disclosure and make those skilled in the art fully receive the scope of the present invention. In the drawings, for clarity purpose, the size and the relative size of layers and areas may be exaggerated. In the drawings, same reference number indicates same element.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

Exemplified embodiments described herein are with reference of the cross-sectional view of the schematic diagram of an idealized embodiment (and intermediate structures) of the present invention. Thus, shape alteration due to, for example, manufacturing techniques and/or tolerances can be expected. Accordingly, embodiments of the present invention should not be limited to the particular shapes of regions illustrated herein but are to include deviations in shapes caused by, for example, manufacturing.

For a thorough understanding of the present invention, the detailed steps will be set forth in detail in the following description in order to explain the technical solution of the present invention. The preferred embodiments of the present invention is described in detail as follows, however, in addition to the detailed description, the present invention also may have other embodiments.

In the monocrystal growth furnace, the reflective screen is able to prevent the heat radiation from the molten silicon and the quartz crucible to the surface of the silicon crystal, increase the vertical temperature gradient of the ingot, control the crystal growth rate and the internal defects such as the crystal originated particle (COP) and the like. Further, the reflective screen is able to regulate the flow of inert gas fed from the upper part of the furnace to pass the surface of the molten silicon with a faster flow rate, thereby the contents of oxygen and impurities within the crystal can be controlled. However, the known reflective screen cannot effectively prevent the thermal transmittance from the outer cylinder to the inner cylinder. The unnecessary thermal transmittance causes the additional heating efficiency, increases the temperature of the inner cylinder, reduces the temperature of the outer cylinder, causes the undesired temperature gradient of the ingot, and makes the silicon oxides evaporated from the molten silicon condensate on the outer cylinder of the reflective screen. Thereby, polycrystalline may be caused by the silicon oxides (SiOx) falling into the molten silicon.

To solve the above problems, the present application provides a reflective screen of a monocrystal growth furnace and the monocrystal growth furnace. The reflective screen comprises an inner cylinder, an outer cylinder, a thermal insulating material sandwiched between the inner and the outer cylinders, and a thermal insulating pad disposed at the joint of the inner and the outer cylinders. The reflective screen of the present application is able to decrease the thermal transmittance from the outer cylinder to the inner cylinder, increase the vertical temperature gradient of the ingot, and prevent or decrease the silicon oxides evaporated from the molten silicon to condensate on the outer cylinder of the reflective screen. Thereby, polycrystalline caused by the oxides falling into the molten silicon can be reduced. Moreover, the thermal power required during the growth of monocrystalline silicon can be reduced because of the reduction of unnecessary thermal transmittance. The monocrystal growth furnace of the present application possesses the same advantages because it comprises the reflective screen as described above.

To completely understand the present application, the structure and/or the process is provided and described in detail to illustrate the technical means provided in the present application. The preferred embodiments are described as follows, but the present application still has other embodiments.

### Example 1

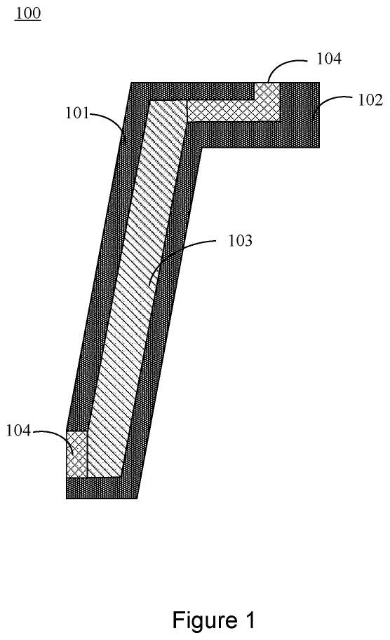

Referring to FIG. 1, according to one embodiment of the present application, the reflective screen 100 of the monocrystal growth furnace is described in detail.

As shown in FIG. 1, the reflective screen 100 comprises an inner cylinder 101, an outer cylinder 102, a thermal insulating material 103 sandwiched between the inner cylinder 101 and the outer cylinder 102, and a thermal insulating pad 104 disposed at the joint of the inner cylinder 101 and the outer cylinder 102.

In one embodiment, the reflective screen 100 comprises an inverted cone-shaped body and an extension part extended from the upper end of the body. The vertical sectional shape of the body is an inverted cone-shape, i.e. narrow bottom and wide top, thereby the thermal transmittance from the molten silicon and the heater to the monocrystalline silicon can be prevented. While the reflective screen 100 is applied in the monocrystal growth furnace, the bottom of the body is near the surface of the molten silicon.

The reflective screen 100 comprises the inner cylinder 101 and the outer cylinder 102. The inner cylinder 101 and the outer cylinder 102 form a sandwich structure, and the thermal insulating material 103 is filled in the sandwich structure. The material of the inner cylinder 101 and/or the outer cylinder 102 includes a carbon/carbon composite (C/C) and/or a graphene. The thermal insulating material 103 includes, but is not limited, a solid carbon felt. The solid carbon felt has low thermal conductivity, better heat preservation and thermal insulation properties, so that the thermal transmittance from the molten silicon and the heater to the monocrystalline silicon ingot can be reduced, and the temperature of the crystal ingot can be lowered.

The thermal insulating pad 104 is set in the connection part between the inner cylinder 101 and the outer cylinder 102 to reduce the thermal transmittance between the inner cylinder 101 and the outer cylinder 102. The material of the thermal insulating pad 104 has a thermal conductivity less than that of the inner cylinder 101 and the outer cylinder 102. In one embodiment, the material of the thermal insulating pad 104 includes a quartz, which has a thermal conductivity lower than that of graphite and effectively reduces the thermal transmittance between the inner and the outer cylinders 101 and 102 because of its better thermal insulation property. The material comprises the quartz materials subjected to coating treatment or not.

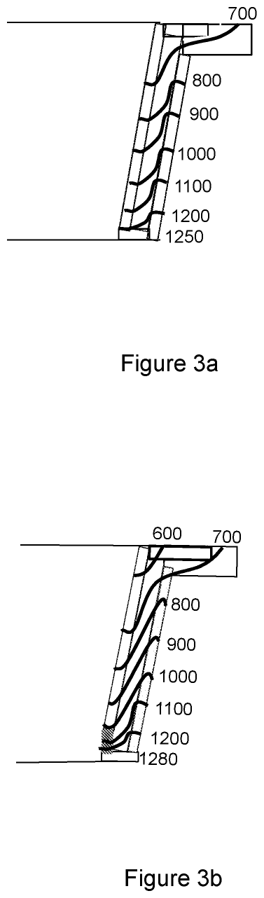

The thermal insulating pad 104 reduces the thermal transmittance between the inner and the outer cylinders 101, 102, in particular, prevents the thermal transmittance from the outer cylinder 102 with higher temperature to the inner cylinder 101 with lower temperature, therefore, the temperature of the outer cylinder 102 increases while the temperature of the inner cylinder 101 decreases. As shown in FIGS. 3a and 3b, the digital analog software such as FEMAG, CGSim and the like is applied for the calculation. Compared with the currently known reflective screen, the reflective screen 100 of the present application has the thermal insulating pad, and the temperature of the inner cylinder 101 decreases by 30-150° C. in average while the temperature of the outer cylinder 102 increases by 10-100° C. in average. Decrease of the temperature of the inner cylinder 101 is able to enhance the heat radiation from the ingot surface to the inner cylinder 101, and increases the temperature gradient of the ingot. Increase of the temperature of the outer cylinder 102 is able to prevent or reduce the vapor of silicon oxides (SiOx) evaporated from the molten silicon surface to condensate on the outer cylinder 102. Thereby, polycrystalline caused by the silicon oxides (SiOx) falling into the molten silicon can be reduced. At the same time, the axial temperature difference of the crucible can be reduced, and the inner stress distribution of the crucible can be moderated. Moreover, the thermal power required during the growth of monocrystalline silicon can be reduced because of the reduction of unnecessary thermal transmittance between the inner cylinder 101 and the outer cylinder 102.

At least one of the thermal insulating pad 104 is included in the reflective screen. In one embodiment, the thermal insulating pad 104 comprises a first thermal insulating pad disposed on the bottom of the inner cylinder 101 and/or a second thermal insulating pad disposed on the top of the inner cylinder 101. On the bottom of the inner cylinder 101, the first thermal insulating pad is set vertically or in a slant to reduce the thermal transmittance between the inner cylinder 101 and the outer cylinder 102. The second thermal insulating pad is set on the edge of the top of the inner cylinder 101, and the joint of the outer cylinder 102. In particular, the second thermal insulating pad is set on the edge of the extension part. The second thermal insulating pad has a bending structure, which is partially embedded in the joint of the inner and the outer cylinders 101, 102 and partially filled in the bending part between the inner and the outer cylinders 101, 102, thereby, the thermal transmittance of the connection part between the tops of the inner and the outer cylinders 101, 102 can be reduced more effectively.

In the present application, the reflective screen of the monocrystal growth furnace has the thermal insulating pad, so that it is able to reduce the thermal transmittance from the outer cylinder to the inner cylinder, increases the vertical temperature gradient of the ingot, prevent or decrease the silicon oxides evaporated from the molten silicon to condensate on the outer cylinder of the reflective screen. Thereby, polycrystalline caused by the oxides falling into the molten silicon can be reduced. Moreover, the thermal power required during the growth of monocrystalline silicon can be reduced because of the reduction of unnecessary thermal transmittance.

### Example 2

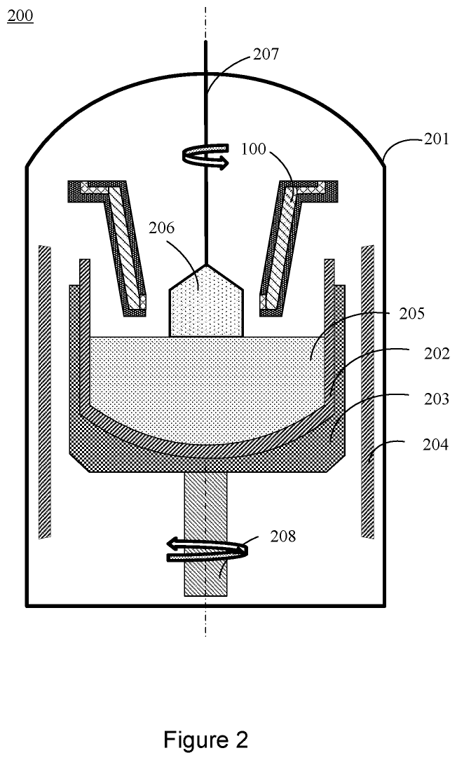

Referring to FIG. 2, according to one embodiment of the present application, the monocrystal growth furnace 200 is described in detail. The monocrystal growth furnace 200 includes the reflective screen 100 as described above. The monocrystal growth furnace 200 includes a furnace body, a crucible disposed in the furnace body, and a reflective screen located above the crucible. The details of the reflective screen is as described above.

As shown in FIG. 2, the monocrystal growth furnace of the present application comprises a furnace body 201, a crucible disposed in the furnace body 201. The crucible comprises a quartz crucible 202 and a graphite crucible 203. The quartz crucible 202 is used to carry a silicon material such as polycrystalline silicon. The silicon material contained in the quartz crucible is heated to be a silicon melt 205. The quartz crucible 202 is covered with the graphite crucible 203. The graphite crucible 203 supports the quartz crucible 202 during the heating step. A heater 204 is set outside the graphite crucible 203. The reflective screen 100 is disposed above the quartz crucible 202. The reflective screen 100 extends downward and surrounds the growth area of the monocrystalline silicon 206 to block the direct heat radiation from the heater 204 and the silicon melt 205 to the growing monocrystalline silicon 206. Thereby the temperature of the monocrystalline silicon 206 can be lowered. At the same time, the reflective screen 100 is able to enhance the heat dissipation of the monocrystalline silicon 206 by concentrating the argon gas and directly spraying to the silicon growth interface. The reflective screen comprises an inner cylinder, an outer cylinder, a thermal insulating material sandwiched between the inner and the outer cylinders, and a thermal insulating pad disposed at the joint of the inner and the outer cylinders. Its concrete structure is as described above.

The monocrystal growth furnace 200 further comprises a seed axis 207 and a crucible axis 208, which are set vertically. The seed axis 207 is disposed above the quartz crucible 202. A seed crystal is clamped on the bottom of the seed axis 207, and a drive unit connects to the top of the seed axis 207 to rotate and slowly pull upward. The crucible axis 208 is disposed on the bottom of the graphite crucible 203, and a drive unit connects to the bottom of the crucible axis 208 to rotate the crucible.

In the present application, the reflective screen applied in the monocrystal growth furnace has the thermal insulating pad, so that it is able to reduce the thermal transmittance from the outer cylinder to the inner cylinder, increases the vertical temperature gradient of the ingot, prevent or decrease the silicon oxides evaporated from the surface of the silicon melt to condensate on the outer cylinder of the reflective screen. Thereby, polycrystalline caused by the oxides falling into the silicon melt can be reduced. Moreover, the thermal power required during the growth of monocrystalline silicon can be reduced because of the reduction of unnecessary thermal transmittance.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure. The scope of the present invention is defined by the appended claims and their equivalent scope.

What is claimed is:

1. A reflective screen of a monocrystal growth furnace comprising an inner cylinder, an outer cylinder, a thermal insulating material sandwiched between the inner and the outer cylinders, and a thermal insulating pad disposed at the joint of the inner and the outer cylinders.

2. The reflective screen of claim 1, wherein the material of the thermal insulating pad comprises quartz.

3. The reflective screen of claim 2, wherein the quartz is subjected to a coating treatment.

4. The reflective screen of claim 1, wherein the reflective screen comprises at least one thermal insulating pad.

5. The reflective screen of claim 1, wherein the thermal insulating pad comprises a first thermal insulating pad disposed on the bottom of the inner cylinder and/or a second thermal insulating pad disposed on the top of the inner cylinder.

6. The reflective screen of claim 1, wherein the thermal insulating pad comprises a second thermal insulating pad disposed on the top of the inner cylinder, and the reflective screen comprises an inverted cone-shaped body and an extension part extended from the upper end of the body, and the second thermal insulating pad further comprises a part disposed on the extension part and sandwiched between the inner and the outer cylinders.

7. The reflective screen of claim 1, wherein the material of the inner cylinder and/or the outer cylinder comprises carbon/carbon composite (C/C) and/or graphene.

8. A monocrystal growth furnace comprises:
a furnace body,
a crucible disposed in the furnace body, and
a reflective screen of any of claim 1, the reflective screen is above the crucible.
